(19) United States
(12) Patent Application Publication
(10) Pub. No.: US 2026/0053066 A1
(43) Pub. Date: Feb. 19, 2026

(54) SEMICONDUCTOR PACKAGE INCLUDING A CORE DIE AND MANUFACTURING METHOD FOR THE SAME

(71) Applicant: SAMSUNG ELECTRONICS CO., LTD., SUWON-SI (KR)

(72) Inventor: YOUNGBAE KIM, Suwon-si (KR)

(21) Appl. No.: 19/067,025

(22) Filed: Feb. 28, 2025

(30) Foreign Application Priority Data
Aug. 16, 2024 (KR) 10-2024-0109702

(51) Int. Cl. H01L 25/18; H01L 23/00; H01L 25/00; H10B 80/00; H10D 80/30

(52) U.S. Cl. CPC H01L 25/18; H01L 24/16; H01L 24/32; H01L 24/73; H10D 80/30; H01L 25/50; H01L 2224/16148; H01L 2224/32145; H01L 2224/73204; H01L 2924/1431; H01L 2924/1436; H10B 80/00

(57) ABSTRACT

An embodiment of the present disclosure provides a semiconductor package including: a buffer die; a core die block positioned on the buffer die and including a first core die having a first surface and a second surface which are opposite to each other, a second core die and a third core die which are positioned side by side on the first surface of the first core die; and a molding material surrounding the core die block on the buffer die.

### CROSS-REFERENCE TO RELATED APPLICATION

This application claims priority to and the benefit of Korean Patent Application No. 10-2024-0109702, filed in the Korean Intellectual Property Office on Aug. 16, 2024, the entire contents of which are herein incorporated by reference.

### BACKGROUND

### 1. Technical Field

The present disclosure relates to a semiconductor package including a core die and a manufacturing method therefor.

### 2. Discussion of Related Art

High Bandwidth Memory (HBM) is a type of memory architecture designed to provide high data transfer rates while maintaining power efficiency and a compact footprint. HBM structures may be used in high-performance computing (HPC), graphics processing units (GPUs), artificial intelligence (AI) accelerators, and other applications requiring substantial memory bandwidth.

### SUMMARY

An aspect of the present disclosure attempts to provide a large capacity semiconductor package and a manufacturing method therefor, capable of ameliorating warpage.

Another aspect of the present disclosure attempts to provide a semiconductor package and a manufacturing method therefor, capable of inhibiting or preventing void occurrence in a non-conductive adhesive film (NCF).

Another aspect of the present disclosure attempts to provide a semiconductor package and a manufacturing method therefor, with an improved heat dissipation characteristic.

An embodiment of the present disclosure provides a semiconductor package including: a buffer die; a core die block positioned on the buffer die and including a first core die having a first surface and a second surface which are opposite to each other, a second core die and a third core die which are positioned side by side on the first surface of the first core die; and a molding material surrounding the core die block on the buffer die.

Another embodiment of the present disclosure provides a semiconductor package including: a buffer die; a core die block positioned on the buffer die and including a first core die having a first surface and a second surface which are opposite to each other, a second core die and a third core die positioned side by side on the first surface of the first core die, a first non-conductive adhesive film positioned between the first core die and the second core die, and a second non-conductive adhesive film positioned between the first core die and the third core die; and a molding material surrounding the core die block on the buffer die, wherein the first non-conductive adhesive film and the second non-conductive adhesive film are spaced apart from each other.

Another embodiment of the present disclosure provides a semiconductor package including: a buffer die; a plurality of core die blocks stacked on the buffer die, each core die block of the plurality of core die blocks including a first core die having a first surface and a second surface which are opposite to each other, a second core die and a third core die positioned side by side on the first surface of the first core die, a first non-conductive adhesive film positioned between the first core die and the second core die, and a second non-conductive adhesive film positioned between the first core die and the third core die; and a molding material surrounding the plurality of core die blocks on the buffer die, wherein the first non-conductive adhesive film and the second non-conductive adhesive film are spaced apart from each other.

Another embodiment of the present disclosure provides a method for manufacturing a semiconductor package, including: forming a core die block including a first core die, a second core die, and a third core die by arranging the second core die and the third core die side by side on the first core die; positioning the core die block on a buffer die; and molding the core die block on the buffer die.

In an embodiment, in the forming of the core die block, the second core die and the third core die may be respectively positioned on the first core die using a first non-conductive adhesive film and a second non-conductive adhesive film, and the first non-conductive adhesive film and the second non-conductive adhesive film may be spaced apart from each other on the first core die of the core die block.

In an embodiment, in the positioning of the core die block on the buffer die, the core die block may be positioned on the buffer die using a first non-conductive adhesive film and a second non-conductive adhesive film spaced apart from each other on the first core die.

In an embodiment, a method may include positioning a fourth core die on the core die block to extend over the second core die and the third core die.

In an embodiment, a method may include positioning a fourth core die and a fifth core die side by side on the buffer die, which is performed prior to the positioning of the core die block on the buffer die.

According to an aspect of the present disclosure, it may be possible to provide a large capacity semiconductor package and a manufacturing method therefor, capable of ameliorating warpage.

According to another aspect of the present disclosure, it may be possible to provide a semiconductor package and a manufacturing method therefor, capable of preventing void occurrence in a non-conductive adhesive film (NCF).

According to another aspect of the present disclosure, it may be possible to provide a semiconductor package and a manufacturing method therefor, with an improved heat dissipation characteristic.

### BRIEF DESCRIPTION OF THE DRAWINGS

FIG. 1 illustrates a cross-sectional view of a semiconductor package according to an embodiment.

FIG. 2 illustrates an enlarged view of a core die block of FIG. 1.

FIG. 3 illustrates a cross-sectional view of a semiconductor package according to another embodiment.

FIG. 4 illustrates a cross-sectional view of a semiconductor package according to another embodiment.

FIG. 5 illustrates a cross-sectional view of a semiconductor package according to another embodiment.

FIG. 6 illustrates a cross-sectional view of a semiconductor package according to another embodiment.

FIG. 7 illustrates a schematic manufacturing process of a semiconductor package according to an embodiment of the present disclosure.

FIG. 8 illustrates a schematic manufacturing process of a semiconductor package according to an embodiment of the present disclosure.

FIG. 9 illustrates a schematic manufacturing process of a semiconductor package according to an embodiment of the present disclosure.

FIG. 10 illustrates a schematic manufacturing process of a semiconductor package according to an embodiment of the present disclosure.

FIG. 11 illustrates a schematic manufacturing process of a semiconductor package according to an embodiment of the present disclosure.

FIG. 12 illustrates a schematic manufacturing process of a semiconductor package according to an embodiment of the present disclosure.

FIG. 13 illustrates a schematic manufacturing process of a semiconductor package according to an embodiment of the present disclosure.

### DETAILED DESCRIPTION

The present disclosure will be described more fully hereinafter with reference to the accompanying drawings, in which embodiments of the disclosure are shown. As those skilled in the art would realize, embodiments may be modified in various different ways, all without departing from the spirit or scope of the present disclosure.

To clearly describe the present disclosure, parts that are irrelevant to the description may be omitted or simplified, and like numerals refer to like or similar components throughout the specification.

Further, since sizes and thicknesses of constituent members shown in the accompanying drawings may be arbitrarily given for better understanding and ease of description, the present disclosure is not limited to the illustrated sizes and thicknesses. In the drawings, the thicknesses of layers, films, panels, regions, etc., may be exaggerated for clarity. In the drawings, for better understanding and ease of description, the thicknesses of some layers and areas may be exaggerated.

Throughout this specification and the claims that follow, when it is described that an element is “coupled/connected” to another element, the element may be “directly coupled/connected” to the other element or “indirectly coupled/connected” to the other element through a third element. In a similar sense, this includes being “physically connected” as well as being “electrically connected”.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

In addition, throughout the specification, sequence numbers such as first, second, etc. may be used to distinguish a certain component from other components that are the same or similar thereto, and may not necessarily be used to refer to a specific component. Accordingly, a component referred to as a first component in a specific part of this specification may be referred to as a second component in other parts of this specification.

In addition, throughout the specification, singular references to certain elements include references to a plurality of these elements, unless specifically stated to the contrary. For example, “insulating layer” may be used to indicate not only one wiring layer but also a plurality of insulating layers, such as two, three, or more.

Additionally, throughout the specification, references to a first side and a second side may distinguish different sides from each other, and may not necessarily be used to limit it to a specific side. Accordingly, a side referred to as a first side in a specific part of this specification may also be referred to as a second side in other parts of this specification.

Furthermore, throughout the specification, references to directions such as upper surface, upper side, upper portion, lower surface, lower side, lower portion, etc. may be described to aid description and understanding based on the drawings.

Hereinafter, a semiconductor package and a manufacturing method thereof according to embodiments of the present disclosure will be described with reference to the drawings.

A high bandwidth memory (HBM) structure may provide high bandwidth along with expanded memory capacity by implementing a core die stack in which multiple core dies (e.g., DRAMs) are stacked on a buffer die. According to an aspect of the present disclosure, in a semiconductor package, a core die block may include a first core die, and a second core die and a third core die arranged side by side on a surface of the first core die. The code die block may reduce warpage in the semiconductor package and may improve a heat dissipation characteristic of the semiconductor package. The code die block may support improved application of an adhesive between the core dies and between code die blocks disposed in a stack.

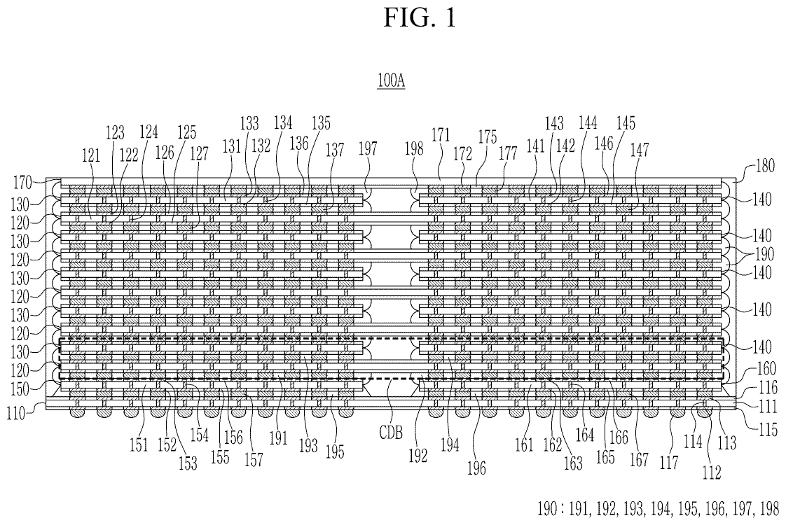

FIG. 1 illustrates a cross-sectional view of a semiconductor package according to an embodiment.

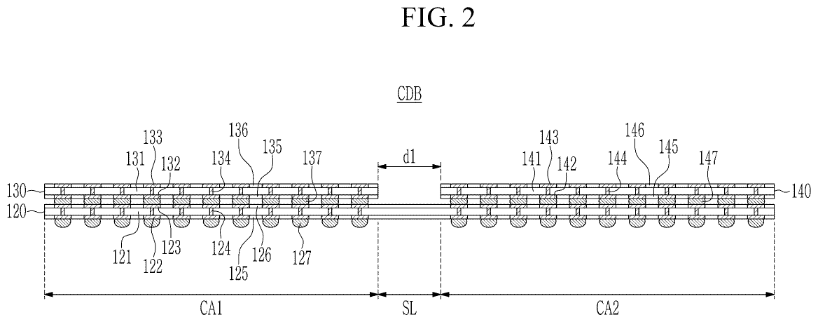

FIG. 2 illustrates an enlarged view of a core die block of FIG. 1.

The semiconductor package 100A may include a buffer die 110, one or more core die blocks CDB, and a molding material 180. The core die blocks CDB may be disposed on the buffer die 110. Each core die block CBD may include a plurality of core dies. For example, in FIG. 1, the core die block CBD may include core dies 120, 130, and 140. The molding material 180 may be disposed at end portions of the core die blocks CDB. The molding material 180 may be disposed between the core dies of the core die block CDB. The molding material 180 may be disposed on the buffer die 110. For example, the molding material 180 may be disposed surrounding the core die blocks CDB on the buffer die 110.

The buffer die 110 may form a high bandwidth memory (HBM) together with core dies positioned on the buffer die 110. The buffer die 110 may perform roles such as ensuring data transmission integrity through data buffering and efficiently distributing signals and power to core dies. The buffer die 110 may be a logic die, and may also be referred to as a base die in the technical field to which the present disclosure pertains. A cross-sectional width of the buffer die 110 may be equal to or similar to a cross-sectional width of the semiconductor package 100A.

The buffer die 110 may include a semiconductor substrate 111, a first pad 112, a second pad 113, a through via 114, a first insulating layer 115, a second insulating layer 116, and a conductive bump 117. The first pad 112 may be positioned on a lower surface of the semiconductor substrate 111. The second pad 113 may be positioned on an upper surface of the semiconductor substrate 111. The through via 114 may extend through the semiconductor substrate 111 and electrically connect the first pad 112 and the second pad 113. The first insulating layer 115 may be disposed on a lower surface of the semiconductor substrate 111. The second insulating layer 116 may be disposed on the upper surface of the semiconductor substrate 111. The conductive bump 117 may be positioned on the first pad 112.

A type of the semiconductor substrate 111 is not particularly limited, and may include a semiconductor element such as silicon (Si) or germanium (Ge), or a compound semiconductor such as gallium arsenide (GaAs) or indium arsenide (InAs). Individual elements and circuits may be provided on a surface of the semiconductor substrate 111.

The first pad 112 and the second pad 113 may each provide electrical connections between the buffer die 110 and other components. For example, the first pad 112 may electrically connect the buffer die 110 to another configuration (e.g., a main board) on which the semiconductor package 100A is mounted, and the second pad 113 may electrically connect the buffer die 110 to the core dies 120, 130, 140, 150, 160, 170. The first pad 112 and the second pad 113 may be formed of conductive materials such as copper (Cu) or aluminum (Al).

The through via 114 may electrically connect the first pad 112 and the second pad 113 through the semiconductor substrate 111. The through via 114 may formed of a conductive material such as copper (Cu), tungsten (W), silver (Ag), nickel (Ni), or polysilicon. An insulating barrier film may be provided between an outer surface of the through via 114 and the semiconductor substrate 111.

The first insulating layer 115 and the second insulating layer 116 may protect the buffer die 110. For electrical connection between the first pad 112 and the second pad 113, the first insulating layer 115 may expose at least a portion of a lower surface of the first pad 112, and the second insulating layer 116 may expose at least a portion of an upper surface of the second pad 113. Each of the first insulating layer 115 and the second insulating layer 116 may be formed of an organic material such as polyimide (PI) or a silicon carbon nitride (SiCN), or an inorganic material such as a silicon oxide or a silicon nitride.

The conductive bump 117 may be positioned on a lower surface of the first pad 112. The conductive bump 117 may provide an electrical connection between the first pad 112 and another component (e.g., a main board) to which the first pad 112 is connected. The conductive bump 117 may be formed of a conductive material such as solder. The conductive bump 117 may be provided as a plurality of conductive bumps 117 arranged, spaced apart for each other, on a lower side of the buffer die 110.

The core die blocks (CDBs) may be stacked on the buffer die 110, and may be electrically connected to the buffer die 110. A number of the core die blocks (CDBs) is not particularly limited and may be more or less than that shown in the drawings.

Each core die block (CDB) may include a first core die 120, a second core die 130, and a third core die 140. The second core die 130 and the third core die 140 may be arranged side by side on a surface of the first core die 120.

The first core die 120 may include a first circuit area CA1, a second circuit area CA2, and a scribe lane area SL positioned between the first circuit area CA1 and the second circuit area CA2. The first core die 120 may have a structure in which the scribe lane area SL is not sawed at a wafer level, and a circuit may not exist in the scribe lane area SL. For example,, different circuits may be provided in each of the first circuit area CA1 and the second circuit area CA2. The first circuit area CA1 and the second circuit area CA2 may be separated from each other by the scribe lane area SL, and may be electrically insulated from each other. However, a circuit may also be formed in the scribe lane area SL and the first circuit area CA1 and the second circuit area CA2 may be electrically connected.

By including an unsawn scribe lane area SL, a cross-sectional width of the first core die 120 may be wider than that of a cross-sectional width of each of the second core die 130 and the third core die 140. Further, in the case that the second core die 130 and the third core die 140 are disposed apart from each other, a cross-sectional area of the first core die 120 may be greater than a sum of cross-sectional areas of the second core die 130 and the third core die 140.

The second core die 130 and the third core die 140 may be arranged side by side on the first core die 120. Each of the second core die 130 and the third core die 140 may be electrically connected to the first core die 120. For example, the second core die 130 may be positioned on the first circuit area CA1 of the first core die 120 to be electrically connected to the first circuit area CA1, and the third core die 140 may be positioned on the second circuit area CA2 of the first core die 120 to be electrically connected to the second circuit area CA2.

Second core dies 130 and first circuit areas CA1 of the first core die 120 may be electrically connected to each other and may constitute a first memory, and third core dies 140 and second circuit areas CA2 of the first core die 120 may be electrically connected to each other and may constitute a second memory. The first memory and the second memory may provide memory capacity of a semiconductor package 100A. The first memory and the second memory may be independent memories, or may provide a shared memory space.

The second core die 130 and the third core die 140 may have substantially a same thickness. In the present disclosure, the term ‘substantially identical’ is a concept that includes not only a case where features or components may be completely identical, but also a range of characteristics, for each in a range of error that may occur in a manufacturing process. The core die blocks (CDBs) may be stacked by forming thicknesses of the second core die 130 and the third core die 140 to be the same.

A distance d1 between the second core die 130 and the third core die 140 may be about 400 μm or more. If the distance d1 between the second core die 130 and the third core die 140 is less than about 400 μm, a process problem may occur in arranging the core dies 130 and 140, and it may be difficult to evenly fill the molding material 180 between the second core die 130 and the third core die 140.

The core die blocks (CDBs) may be manufactured separately by arranging the second core die 130 and the third core die 140 side by side on the first core die 120. The core die blocks (CDBs) may be stacked on the buffer die 110 in an assembly process. The core die blocks (CDBs) may be stacked such that the second core dies 130 may overlap each other vertically and the third core dies 140 may overlap each other vertically. However, the core dies 120, 130, and 140 may not necessarily have to be positioned on the buffer die 110 in a state where they are assembled into a core die block (CDB). For example, the first core die 120, the second core die 130, and the third core die 140 may be sequentially positioned on the buffer die 110.

Each core die block (CDB) may be positioned on the buffer die 110 such that the first core die 120 faces the buffer die 110. Accordingly, the first core die 120 may be extended into a space between the buffer die 110 and the second core die 130, and a space between the buffer die 110 and the third core die 140. However, according to another embodiment, each core die block (CDB) may be arranged such that the second core die 130 and the third core die 140 face the buffer die 110, and the second core die 130 and the third core die 140 may be arranged between the buffer die 110 and the first core die 120.

In an embodiment, the semiconductor package 100A may further include a fourth core die 150 and a fifth core die 160 positioned side by side between the buffer die 110 and the core die block (CDB).

The fourth core die 150 and the fifth core die 160 may be electrically connected to the buffer die 110 and the core die block (CDB). For example, the fourth core die 150 may be electrically connected to the first circuit area CA1 of the first core die 120 and the second core die 130, and the first circuit area CA1 of the first core die 120, the second core die 130 and the fourth core die 150 may form a first memory. Furthermore, the fifth core die 160 may be electrically connected to the second circuit area CA2 of the first core die 120 and the third core die 140, and the second circuit area CA2 of the first core die 120, the third core die 140 and the fifth core die 160 may form a second memory.

The fourth core die 150 and the second core die 130 may overlap each other in the vertical direction, and the fifth core die 160 and the third core die 140 may overlap each other in the vertical direction.

Furthermore, a cross-sectional width of each of the fourth core die 150 and the fifth core die 160 may be equal to or similar to a cross-sectional width of each of the second core die 130 and the third core die 140.

In an embodiment, the semiconductor package 100A may further include a sixth core die 170 positioned on the core die block (CDB) to extend over the second core die 130 and the third core die 140.

The sixth core die 170 may be electrically connected to the buffer die 110, the core die block (CDB), the fourth core die 150, and the fifth core die 160. Furthermore, the sixth core die 170 may have a first circuit area, a second circuit area, and a scribe lane area positioned between the first circuit area and the second circuit area (e.g., a similar structure to that of the first core die 120). The first circuit area of the sixth core die 170 may be electrically connected to, e.g., the first circuit areas CA1 of the first core die 120, the second core die 130, and the fourth core die 150, and may together constitute the first memory. Furthermore, the second circuit area of the sixth core die 170 may be electrically connected to, e.g., the second circuit areas CA2 of the first core die 120, the third core die 140, and the fifth core die 160, and may together constitute the second memory.

The sixth core die 170 and the first core die 120 may overlap each other in the vertical direction.

A cross-sectional width of the sixth core die 170 may be equal to or similar to a cross-sectional width of the first core die 120.

The sixth core die 170 may be exposed to an upper surface of the molding material 180. In an embodiment, an upper surface of the sixth core die 170 may be coplanar with the upper surface of the molding material 180. The sixth core die 170 may be encapsulating by the molding material 180, and a surface of the sixth core die 170 may be exposed to the upper surface of the molding material 180 by grinding the molding material 180. A portion of the sixth core die 170 may be ground together when grinding the molding material 180. A semiconductor package having an improved heat dissipation characteristic may be provided by exposing the sixth core die 170 to the upper surface of the molding material 180.

Each of the core dies 120, 130, 140, 150, 160, and 170 may be a memory die such as a dynamic random access memory, and may also be referred to as a node die or a slave die in the technical field to which the present disclosure pertains.

The core dies 120, 130, 140, 150, 160, and 170 may include semiconductor substrates 121, 131, 141, 151, 161, and 171, first pads 122, 132, 142, 152, 162, and 172, second pads 123, 133, 143, 153, and 163, through vias 124, 134, 144, 154, and 164, first insulating layers 125, 135, 145, 155, 165, and 175, second insulating layers 126, 136, 146, 156, and 166, and conductive bumps 127, 137, 147, 157, 167, and 177. The first pads 122, 132, 142, 152, 162, and 172 may be disposed on lower surfaces of the semiconductor substrates 121, 131, 141, 151, 161, and 171. The second pads 123, 133, 143, 153, and 163 may be disposed on upper surfaces of the semiconductor substrates 121, 131, 141, 151, and 161. The first pads 122, 132, 142, 152, and 162 and the second pads 123, 133, 143, 153, and 163 may be electrically connected by the through vias 124, 134, 144, 154, and 164. The first insulating layers 125, 135, 145, 155, 165, and 175 may be disposed on the lower surfaces of semiconductor substrates 121, 131, 141, 151, 161, and 171. The second insulating layers 126, 136, 146, 156, and 166 may be disposed on the upper surfaces of semiconductor substrates 121, 131, 141, 151, and 161. The conductive bumps 127, 137, 147, 157, 167, and 177 may be disposed on the first pads 122, 132, 142, 152, 162, and 172. The sixth core die 170, which may be positioned at an uppermost side among the core dies. The sixth core die 170 may not include a second pad, a through via, or a second insulating layer. For example, the sixth core die 170 may omit components for connection with another core die positioned at an upper side of the sixth core die 170.

A type of the semiconductor substrates 121, 131, 141, 151, 161, and 171 is not particularly limited, and may include a semiconductor element such as silicon (Si) or germanium (Ge), or a compound semiconductor such as gallium arsenide (GaAs) or indium arsenide (InAs). Individual elements and circuits may be provided on a surface of the semiconductor substrates 121, 131, 141, 151, 161, and 171.

The first pads 122, 132, 142, 152, 162, and 172 may be electrically connected to the second pads 113, 123, 133, 143, 153, and 163 of another core die or buffer die 110 positioned on a lower side of each of the core dies 120, 130, 140, 150, 160, and 170. The second pads 123, 133, 143, 153, and 163 may be electrically connected to the first pads 122, 132, 142, and 172 of another core die positioned on an upper side of each of the core dies 120, 130, 140, 150, and 160. For example, each of the first pads 122 of the first core die 120 may be electrically connected to the second pads 133 and 143 of the second core die 130 or the third core die 140 of another core die block. Furthermore, the first pads 132 and 142 of the second core die 130 and the third core die 140 may be electrically connected to the second pads 123 of the first core die 120, respectively. The first pads 122, 132, 142, 152, 162, and 172 and the second pads 123, 133, 143, 153, and 163 may be formed of conductive materials such as copper (Cu) or aluminum (Al).

The through vias 124, 134, 144, 154, and 164 may electrically connect the first pads 122, 132, 142, 152, and 162 and the second pads 123, 133, 143, 153, and 163 by extending through the semiconductor substrates 121, 131, 141, 151, and 161. The through vias 124, 134, 144, 154, and 164 may formed of a conductive material such as copper (Cu), tungsten (W), silver (Ag), nickel (Ni), or polysilicon. An insulating barrier film may be provided between outer surfaces of the through vias 124, 134, 144, 154, and 164 and the semiconductor substrates 121, 131, 141, 151, and 161.

The first insulating layers 125, 135, 145, 155, 165, and 175 and the second insulating layers 126, 136, 146, 156, and 166 may protect the core dies 120, 130, 140, 150, 160, and 170. For electrical connection between the first pads 122, 132, 142, 152, 162, and 172 and the second pads 123, 133, 143, 153, and 163, the first insulating layers 125, 135, 145, 155, 165, and 175 may expose at least a portion of the lower surfaces of the first pads 122, 132, 142, 152, 162, and 172, and the second insulating layers 126, 136, 146, 156, and 166 may expose at least a portion of the upper surfaces of the second pads 123, 133, 143, 153, and 163. Each of the first insulating layers 125, 135, 145, 155, 165, and 175 and the second insulating layers 126, 136, 146, 156, and 166 may be formed of an organic material such as polyimide (PI) or a silicon carbon nitride (SiCN), or an inorganic material such as a silicon oxide or a silicon nitride.

The conductive bumps 127, 137, 147, 157, 167, and 177 may be arranged on lower surfaces of the first pads 122, 132, 142, 152, 162, and 172 and may provide electrical connection between each core die 120, 130, 140, 150, 160, and 170 and another core die or buffer die arranged on a lower side of each core die. The conductive bumps 127, 137, 147, 157, 167, and 177 may be arranged on the lower surfaces of the first pads 122, 132, 142, 152, 162, and 172, and may be arranged on another core die or buffer die, and accordingly, it may also be understood that they may be arranged between the core dies 120, 130, 140, 150, 160, and 170, or between the core die and the buffer die 110. In the present disclosure, among the conductive bumps 127, 137, 147, 157, 167, and 177, the conductive bumps 127, 137, and 147 arranged on the lower surfaces of the first core die 120, the second core die 130, and the third core die 140 may be described as being included in a core die block (CDB). Each of the conductive bumps 127, 137, 147, 157, 167, and 177 may be formed of a conductive material such as solder.

The molding material 180 may surround a side surface of each of the core die blocks (CDB) in a stack, the fourth core die 150, the fifth core die 160, and the sixth core die 170 on the buffer die 110. The molding material 180 may cover the non-conductive adhesive film 190. The molding material 180 may be made of an insulating material such as epoxy molding compound (EMC). When manufacturing the semiconductor package 100A, the molding material 180 and the buffer die 110 may be cut together, and a side surface of the molding material 180 may be coplanar with a side surface of the buffer die 110 in a vertical direction. According to another embodiment, the molding material 180 may also cover the side surface of the buffer die 110. For example, a cross-sectional width of the buffer die 110 may be equal to or similar to a cross-sectional width of the first core die 120 and the sixth core die 170.

The semiconductor package 100A may further include non-conductive adhesive films (NCFs) 190 arranged on the lower surfaces of the core dies 120, 130, 140, 150, 160, and 170, and the non-conductive adhesive films (NCFs) 190 may bond each core die to another core die or buffer die positioned below each core die. The non-conductive adhesive films 190 may be arranged on the lower surfaces of the core dies 120, 130, 140, 150, 160, and 170 to be arranged on other core dies or buffer dies, and may also be understood as being arranged between the core dies or between the core dies and the buffer dies 110. In the present disclosure, among the non-conductive adhesive films 190, the non-conductive adhesive films 191, 192, 193, and 194 positioned on the lower surfaces of the first core die 120, the second core die 130, and the third core die 140 may be described as being included in a core die block (CDB). However, for convenience of illustration, non-conductive adhesive films 191, 192, 193, and 194 are omitted in FIG. 2.

When the core dies 120, 130, 140, 150, 160, and 170 are placed on the buffer die 110, the non-conductive adhesive film 190 may be pressed and deformed. By the action of such deformation of the non-conductive adhesive film 190, each of the non-conductive adhesive films 190 may extend onto side surfaces of the core dies to which the non-conductive adhesive film 190 may be bonded. For example, the non-conductive adhesive films 193 disposed on the first core die 120 and the second core die 130 may extend onto the side surface of each of the first core die 120 and the second core die 130, and different films of the non-conductive adhesive films 193 may contact each other. For example, side surfaces of the first core die 120, the second core die 130, and the third core die 140 may be covered by the non-conductive adhesive film 190. For example, the non-conductive adhesive film 193 may extend onto the side surface of each of the first core die 120 and the second core die 130, and the non-conductive adhesive film 194 may extend onto the side surface of each of the first core die 120 and the third core die 140. The non-conductive adhesive film 193 extending onto the side surface of each of the first core die 120 and the second core die 130, and the non-conductive adhesive film 194 extending onto the side surface of each of the first core die 120 and the third core die 140 may be spaced apart from each other.

Among the non-conductive adhesive films 190, the non-conductive adhesive films 191, 192, 193, 194, 195, 196, 197, and 198 bonded to the buffer die 110, the first core die 120, or the sixth core die 170 may be spaced apart from each other. For example, the non-conductive adhesive film 191 and the non-conductive adhesive film 192 may be spaced apart from each other on the lower surface of the first core die 120. Furthermore, the non-conductive adhesive film 193 positioned between the first core die 120 and the second core die 130, and the non-conductive adhesive film 194 positioned between the first core die 120 and the third core die 140, may be spaced apart from each other. Furthermore, the non-conductive adhesive film 195 positioned between the buffer die 110 and the fourth core die 150, and the non-conductive adhesive film 196 positioned between the buffer die 110 and the fifth core die 160, may be spaced apart from each other. Furthermore, the non-conductive adhesive film 197 positioned between the uppermost second core die 130 and the sixth core die 170, and the non-conductive adhesive film 198 positioned between the uppermost third core die 140 and the sixth core die 170, may also be spaced apart from each other. According to the present disclosure, void generation within the non-conductive adhesive films (NCF) may be inhibited or prevented by forming a non-conductive adhesive film 19 separately on the buffer die 110 and the core dies 120 and 170.

The non-conductive adhesive films 190 may cover at least a portion of the conductive bumps 127, 137, 147, 157, 167, and 177 positioned between the core dies 120, 130, 140, 150, 160, and 170, or between the core die 150 and the buffer die 110. For example, the non-conductive adhesive film 191 positioned between the first core die 120 and the third core die 140, and the non-conductive adhesive film 192 positioned between the first core die 120 and the fourth core die 150, may cover at least a portion of the conductive bump 127. Furthermore, the non-conductive adhesive film 193 positioned between the first core die 120 and the second core die 130 may cover at least a portion of the conductive bump 137, and the non-conductive adhesive film 194 positioned between the first core die 120 and the third core die 140 may cover at least a portion of the conductive bump 147.

Meanwhile, a memory capacity may be provided, a method of arranging multiple core die stacks in which core dies (e.g., DRAMs) are stacked on a single buffer die may be provided. For example, the core die stacks may be spaced apart by a certain distance (e.g., more than about 400 μm) for process reasons such as increased stacking difficulty, and an area between the core die stacks may be filled with a molding material such as an epoxy molding compound (EMC). A coefficient of thermal expansion (CTE) of the EMC at a high temperature may increase by about 4 to 6 times compared to that at room temperature, which may impart stress on the semiconductor package and may increase warpage of a semiconductor package. Furthermore, thermal conductivity of the EMC may be relatively low, which may hinder heat dissipation of the semiconductor package when a volume occupied by the EMC in the semiconductor package increases.

According to the present disclosure, the first core die 120 extending on the second core die 130 and the third core die 140 may be provided in addition to the second core dies 130 and the third core dies 140 stacked on the buffer die 110. According to the present disclosure, the warpage of a semiconductor package may be improved (e.g., reduced) by introducing the first core die 120 having a relatively long width (e.g., as compared to the second core die 130 and the third core die 140). Furthermore, a heat dissipation characteristic of the semiconductor package may be improved (e.g., increased) by forming a heat transfer path in a horizontal direction through the first core die 120.

Furthermore, according to the present disclosure, void generation within a NCF may be suppressed by separately positioning the non-conductive adhesive films (NCF) 190 on the core die. For example, when using a single NCF with a long width, void generation may be inhibited or prevented within the non-conductive adhesive film (NCF) 190 by forming the non-conductive adhesive films 191 and 192 spaced apart on the lower surface of the first core die 120. Even if voids are created within the non-conductive adhesive film (NCF) 190, the voids may be discharged to the scribe lane area SL of the first core die 120 when the core die blocks (CDB) are stacked. Furthermore, an interface stress between the molding material 180 and the non-conductive adhesive film (NCF) 190 may be reduced through the first core die 120, which may increase product reliability.

Hereinafter, and to unify the description and terminology of a manufacturing process in this specification and to concisely refer to a structure in which the core dies 120, 130, and 140 are stacked, the term of the core die block (CDB) is used. However, according to the present disclosure methods described herein may be implemented to manufacture other structures, such as a structure in which the core die blocks (CDB) having a same structure or different structures are stacked.

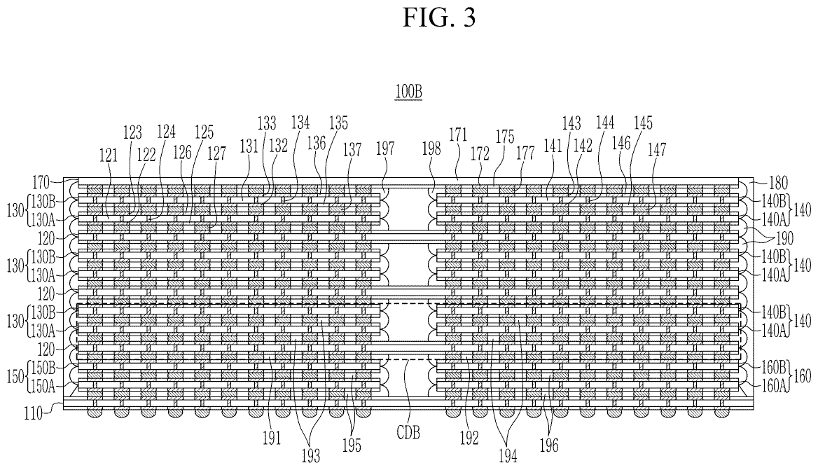

FIG. 3 illustrates a cross-sectional view of a semiconductor package according to an embodiment.

In a semiconductor package 100B, a plurality of second core dies 130 and a plurality of third core dies 140 may be positioned on the first core die 120 of the core die block (CDB). For example, the core die block (CDB) may include the first core die 120, second core dies 130 including a first-second core die 130A and a second-second core die 130B stacked on a first surface of the first core die 120, and third core dies 140 including a first-third core die 140A and a second-third core die 140B stacked spaced apart from the second core dies 130 on the first surface of the first core die 120.

In an embodiment, it may also be configured to include a plurality of fourth core dies 150 and a plurality of fifth core dies 160. For example, the fourth core dies 150 may include a first-fourth core die 150A and a second-fourth core die 150B stacked on the buffer die 110, and the fifth core dies 160 may include a first-fifth core die 160A and a second-fifth core die 160B stacked spaced apart from the fourth core dies 150 on the buffer die 110.

According to another embodiment, the first core die 120 of each core die block (CDB) may also be configured in multiple pieces, and such an embodiment is also included in the present disclosure.

For other configurations, same descriptions as those for the semiconductor package 100A may be applied unless otherwise specifically contradictory.

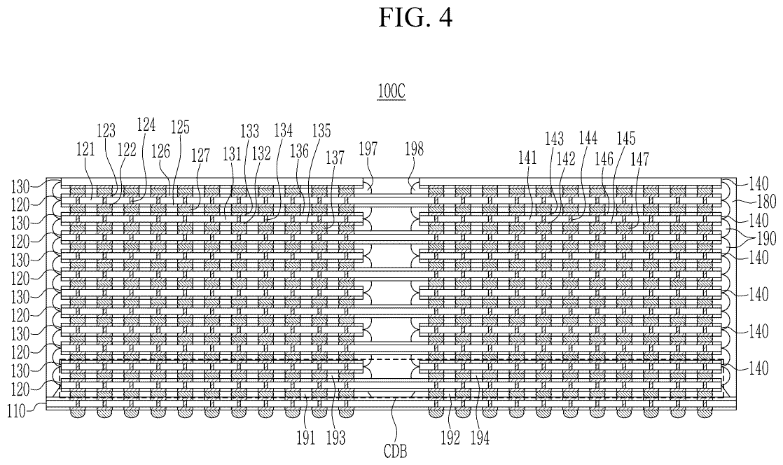

FIG. 4 illustrates a cross-sectional view of a semiconductor package according to another embodiment.

The semiconductor package 100C may omit the fourth core die 150, the fifth core die 160, and the sixth core die 170. In an embodiment, the semiconductor package 100C may include the fourth core die 150 and the fifth core die 160, and may omit the sixth core die 170, or may include the sixth core die 170 and may omit the fourth core die 150 and the fifth core die 160.

For other configurations, same descriptions as those for the semiconductor package 100A may be applied unless otherwise specifically contradictory.

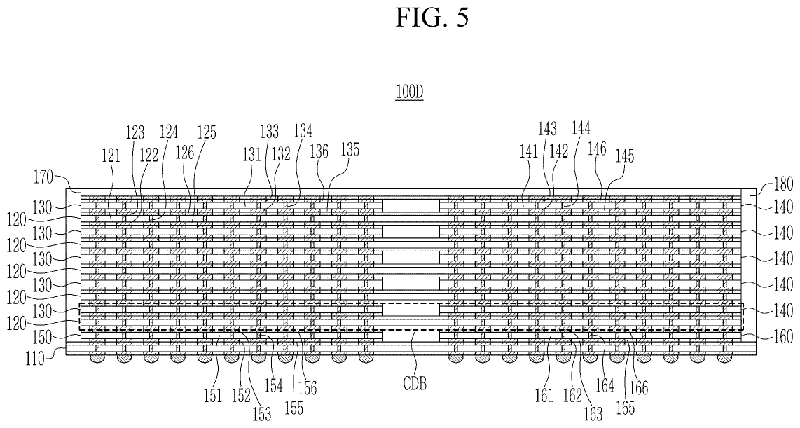

FIG. 5 illustrates a cross-sectional view of a semiconductor package according to another embodiment.

In the semiconductor package 100D, the core dies may be hybrid bonded. Hybrid bonding may be used to stack two structures, such as core die blocks (CDBs), each including metal and a surrounding insulator. Such hybrid bonding may enable thinning of a package thickness and improvement of a signal transmission speed.

In hybrid bonding, the first pads 122, 132, 142, 152, 162, and 172 of the core dies 120, 130, 140, 150, 160, and 170 may contact and be connected to the second pads 123, 133, 143, 153, and 163 of other core dies positioned at lower sides of the core dies, respectively. For example, the first pads 132 and 142 of the second core die 130 and the third core die 140 may contact and be connected to the second pads 123 of the first core die 120, respectively. Furthermore, the first pads 122 of the first core die 120 may contact and be connected to the second pads 133 and 143 of the second core die 130 or the third core die 140 of another core die block.

Furthermore, in hybrid bonding, the first insulating layers 125, 135, 145, 155, 165, and 175 of the core dies 120, 130, 140, 150, 160, and 170 may contact and be connected to the second insulating layers 126, 136, 146, 156, and 166 of other core dies positioned at lower sides of the core dies, respectively.

In an embodiment, the buffer die 110 and the core die may also be hybrid bonded. For example, the second pads 113 of the buffer die 110 may contact and be connected to the first pads 152 and 162 of the fourth core die 150 or the fifth core die 160, respectively. Furthermore, the second insulating layer 116 of the buffer die 110 may contact and be connected to the first insulating layer 155 and 165 of the fourth core die 150 or the fifth core die 160.

For other configurations, same descriptions as those for the semiconductor package 100A may be applied unless otherwise specifically contradictory.

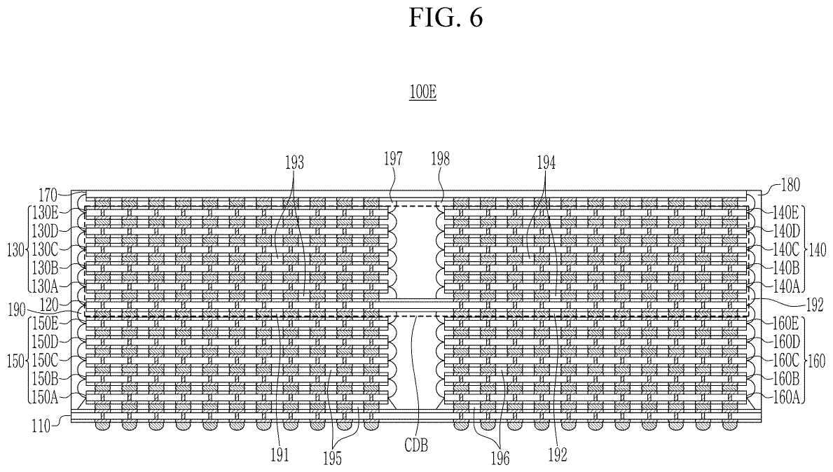

FIG. 6 illustrates a cross-sectional view of a semiconductor package according to another embodiment.

The semiconductor package 100E may include a single instance of a core die block (CDB).

A plurality of second core dies 130 and a plurality of third core dies 140 may be positioned on the first core die 120 of the core die block (CDB). For example, the core die block (CDB) may include the first core die 120, second core dies 130: 130A, 130B, 130C, 130D, and 130E stacked on a first surface of the first core die 120 and third core dies 140: 140A, 140B, 140C, 140D, and 140E stacked side by side with the second core dies 130 on the first surface of the first core die 120. However, a single second core die 130 and/or third core die 140 may be positioned on the first core die 120 of the core die block (CDB).

If necessary, it may also be configured to include a plurality of fourth core dies 150 and a plurality of fifth core dies 160. For example, the fourth core die 150 may include fourth core dies 150A, 150B, 150C, 150D, and 150E stacked on the buffer die 110 and the fifth core dies 160 may include fifth core dies 160A, 160B, 160C, 160D, 160E stacked side by side with the fourth core dies 150 on the buffer die 110. However, a single fourth core die 150 and/or fifth core die 160 may be positioned on the first core die 120 of the core die block (CDB).

For other configurations, same descriptions as those for the semiconductor package 100A may be applied unless otherwise specifically contradictory.

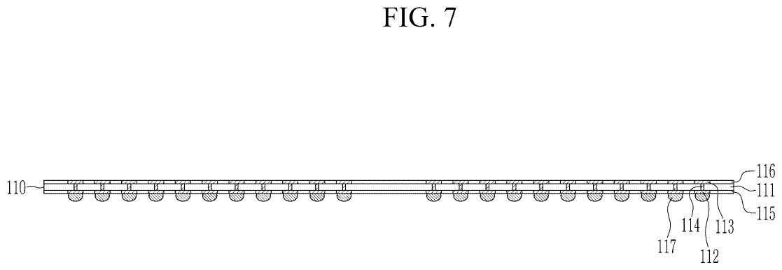

FIG. 7 to FIG. 13 illustrate schematic manufacturing processes of a semiconductor package according to an embodiment of the present disclosure.

A manufacturing method for a semiconductor package may include forming at least one core die block (CDB) including the first core die 120, the second core die 130, and the third core die 140 by arranging the second core die 130 and the third core die 140 side by side on the first core die 120, arranging the core die block (CDB) on the buffer die 110, and molding the core die block (CDB).

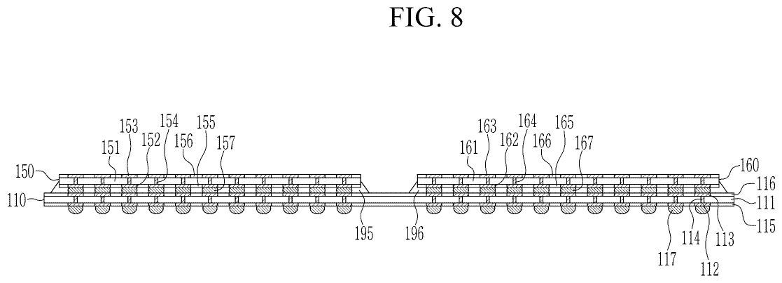

Referring to FIG. 7 and FIG. 8, the buffer die 110 may be prepared, and the fourth core die 150 and the fifth core die 160 may be positioned side by side on the buffer die 110. The fourth core die 150 and the fifth core die 160 may be bonded to the buffer die 110 through non-conductive adhesive films 195 and 196 respectively positioned on lower surfaces thereof.

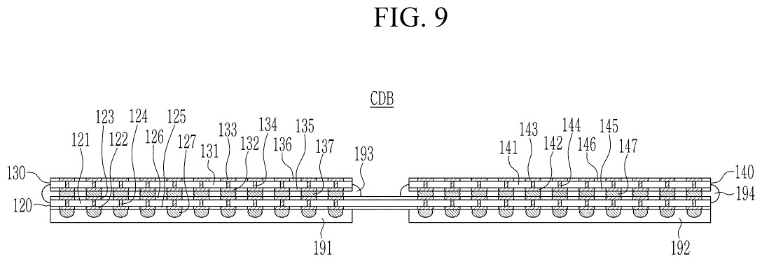

Referring to FIG. 9, one or more core die blocks (CDB) may be formed. A core die block (CDB) may include the second core die 130 and the third core die 140 positioned on the first core die 120 and bonded to the first core die 120 with non-conductive adhesive films 193 and 194 positioned on their lower surfaces, respectively. The non-conductive adhesive films 193 and 194 on the first core die 120 may be spaced apart from each other.

Furthermore, the non-conductive adhesive films 191 and 192 may be spaced apart from each other on the lower surface of the first core die 120 for bonding the core die block (CDB) to another member, e.g., another core die block. The non-conductive adhesive film 191 may be bonded to the fourth core die 150 or the second core die 130 of a lower core die block, and the non-conductive adhesive film 192 may be bonded to the fifth core die 160 or the second core die 130 of the lower core die block.

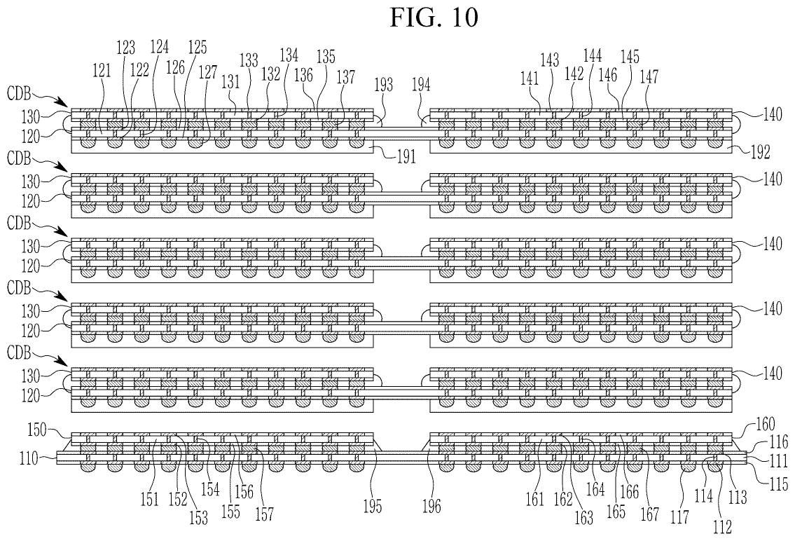

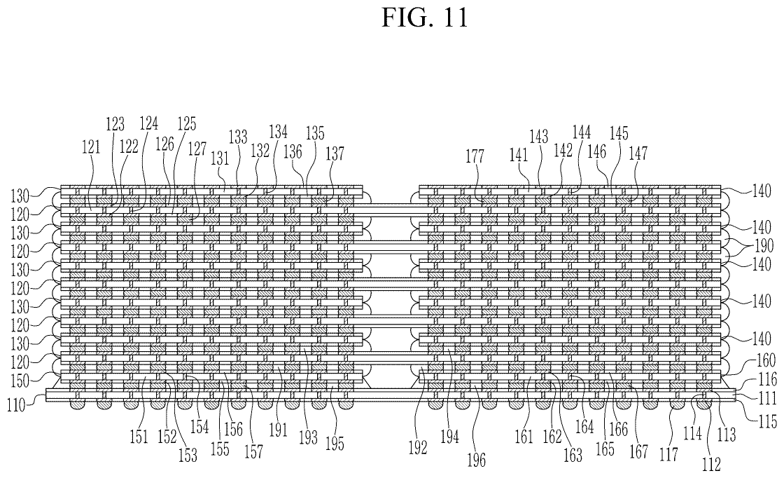

Referring to FIG. 10 and FIG. 11, core die blocks (CDB) may be positioned on the buffer die 110. The core die blocks (CDB) may be sequentially positioned on the buffer die 110 using the non-conductive adhesive films 191 and 192 spaced apart from each other on a lower surface of the first core die 120.

A lowermost core die block among the core die blocks (CDB) may be bonded to the fourth core die 150 and the fifth core die 160 on the buffer die 110 using non-conductive adhesive films 191 and 192. If the fourth core die 150 and the fifth core die 160 are not positioned on the buffer die 110, the lowermost core die block among the core die blocks (CDB) may be directly bonded to the buffer die 110 using the non-conductive adhesive films 191 and 192.

Each core die block (CDB), other than the lowermost core die block, may be positioned directly on another core die block (CDB). Each core die block (CDB) may be directly bonded to another core die block (CDB) using the non-conductive adhesive films 191 and 192.

When positioning core die blocks (CDB), non-conductive adhesive films 191, 192, 193, and 194 may be pressurized and deformed, and voids inside the non-conductive adhesive films 191, 192, 193, and 194 may be discharged to the scribe lane area SL of the first core die 120. Furthermore, the non-conductive adhesive films 191, 192, 193, and 194 may extend onto side surfaces of the core dies to be bonded therethrough.

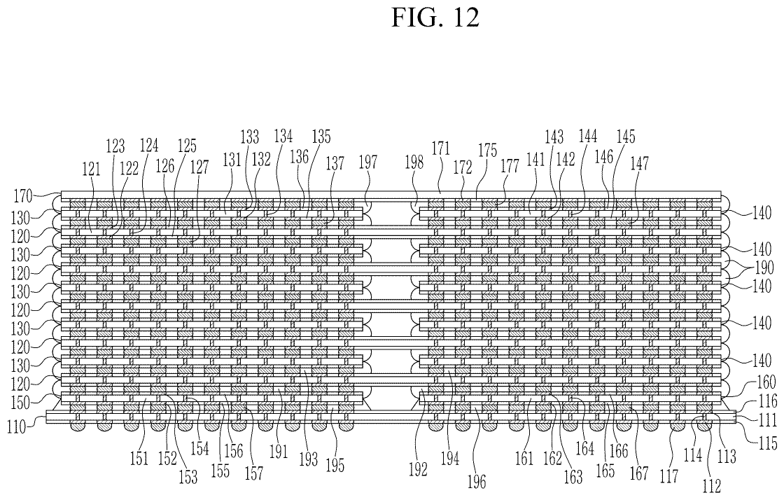

Referring to FIG. 12, the sixth core die 170 may be positioned on the core die block (CDB). The sixth core die 170 may be bonded to an uppermost core die block among the core die blocks (CDB) using the non-conductive adhesive films 197 and 198 spaced apart from each other on a lower surface of the sixth core die 170.

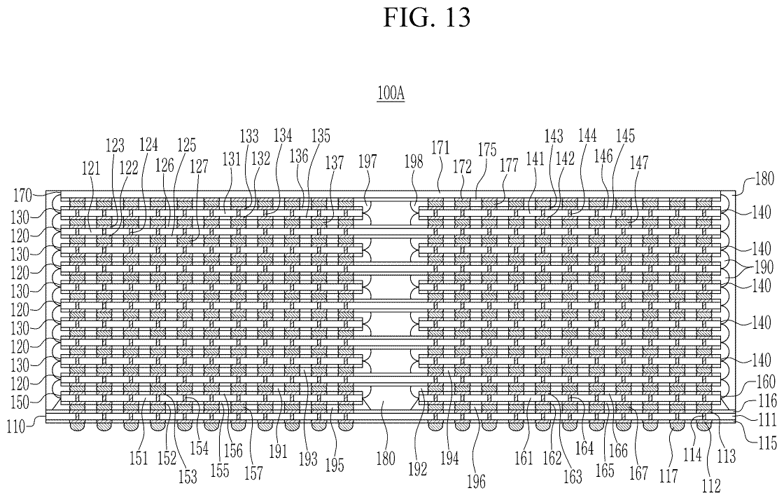

Referring to FIG. 13, the core die blocks (CDB) may be molded with the molding material 180. The fourth core die 150, the fifth core die 160, and the sixth core die 170 may also be molded together with the core die blocks (CDB) during molding. An upper surface of the molding material 180 may be ground to expose the sixth core die 170, and a portion of the sixth core die 170 may be ground together when the molding material 180 is ground.

While this disclosure has been described in connection with what is presently considered to be practical embodiments, it is to be understood that the disclosure is not limited to disclosed embodiments, but, on the contrary, is intended to cover various modifications and equivalent dispositions included within the spirit and scope of the appended claims.

Additionally, embodiments of the present disclosure may be implemented in combination with each other unless there is a particular conflict. Accordingly, embodiments of the present disclosure may be combined, and combinations thereof should also be considered to be included in the present disclosure.

What is claimed is:

1. A semiconductor package comprising:
a buffer die;
a core die block positioned on the buffer die and including a first core die having a first surface and a second surface which are opposite to each other, a second core die and a third core die which are positioned side by side on the first surface of the first core die; and
a molding material surrounding the core die block on the buffer die.

2. The semiconductor package of claim 1, wherein the first core die includes a first circuit area, a second circuit area, and a scribe lane area positioned between the first circuit area and the second circuit area,
the second core die is positioned on the first circuit area and electrically connected to the first circuit area, and
the third core die is positioned on the second circuit area and electrically connected to the second circuit area.

3. The semiconductor package of claim 1, further comprising a fourth core die positioned on the core die block to extend over the second core die and the third core die.

4. The semiconductor package of claim 3, wherein the fourth core die has a same width as the first core die and is exposed by an upper surface of the molding material.

5. The semiconductor package of claim 1, further comprising a fourth core die and a fifth core die arranged side by side on the second surface of the first core die and between the buffer die and the core die block.

6. The semiconductor package of claim 1, wherein the core die block further includes a first conductive bump positioned on the second surface of the first core die, a second conductive bump positioned between the first core die and the second core die, and a third conductive bump positioned between the first core die and the third core die.

7. The semiconductor package of claim 6, further comprising a plurality of non-conductive films covering at least a portion of the first conductive bump, the second conductive bump, or the third conductive bump, respectively.

8. The semiconductor package of claim 1, wherein the first core die includes a first pad and a second pad arranged on the first surface, the second core die includes a third pad, and the third core die includes a fourth pad, and
the first pad contacts and is connected to the third pad, and the second pad contacts and is connected to the fourth pad.

9. The semiconductor package of claim 1, wherein the second core die and the third core die have substantially a same thickness.

10. The semiconductor package of claim 1, wherein a distance between the second core die and the third core die is about 400 μm or more.

11. A semiconductor package comprising:
a buffer die;
a core die block positioned on the buffer die and including a first core die having a first surface and a second surface which are opposite to each other, a second core die and a third core die positioned side by side on the first surface of the first core die, a first non-conductive adhesive film positioned between the first core die and the second core die, and a second non-conductive adhesive film positioned between the first core die and the third core die; and
a molding material surrounding the core die block on the buffer die,
wherein the first non-conductive adhesive film and the second non-conductive adhesive film are spaced apart from each other.

12. The semiconductor package of claim 11, wherein the first non-conductive adhesive film extends over a side surface of each of the first core die and the second core die, and
the second non-conductive adhesive film extends over a side surface of each of the first core die and the third core die.

13. The semiconductor package of claim 11, wherein the core die block further includes a third non-conductive adhesive film and a fourth non-conductive adhesive film spaced apart from each other on the second surface of the first core die.

14. The semiconductor package of claim 11, further comprising:
a fourth core die positioned on the core die block to extend over the second core die and the third core die and having a same width as the first core die; and
a third non-conductive adhesive film positioned between the second core die and the fourth core die, and a fourth non-conductive adhesive film positioned spaced apart from the third non-conductive adhesive film between the third core die and the fourth core die.

15. The semiconductor package of claim 11, further comprising:
a fourth core die and a fifth core die arranged side by side on the second surface of the first core die and between the buffer die and the core die block; and
a third non-conductive adhesive film positioned between the buffer die and the fourth core die, and a fourth non-conductive adhesive film positioned spaced apart from the third non-conductive adhesive film between the buffer die and the fifth core die.

16. A semiconductor package comprising:
a buffer die;
a plurality of core die blocks stacked on the buffer die, each core die block of the plurality of core die blocks including a first core die having a first surface and a second surface which are opposite to each other, a second core die and a third core die positioned side by side on the first surface of the first core die, a first non-conductive adhesive film positioned between the first core die and the second core die, and a second non-conductive adhesive film positioned between the first core die and the third core die; and
a molding material surrounding the plurality of core die blocks on the buffer die,
wherein the first non-conductive adhesive film and the second non-conductive adhesive film are spaced apart from each other.

17. The semiconductor package of claim 16, wherein the first non-conductive adhesive film extends over a side surface of each of the first core die and the second core die, and
the second non-conductive adhesive film extends over a side surface of each of the first core die and the third core die.

18. The semiconductor package of claim 16, wherein each core die block of the plurality of core die blocks further includes a third non-conductive adhesive film and a fourth non-conductive adhesive film spaced apart from each other on the second surface of the first core die.

19. The semiconductor package of claim 16, further comprising:
a fourth core die positioned on the plurality of core die blocks and exposed by an upper surface of the molding material, the fourth core die having a same width as the first core die; and
a third non-conductive adhesive film positioned between the second core die of an uppermost core die block of the plurality of core die blocks and the fourth core die, and a fourth non-conductive adhesive film positioned spaced apart from the third non-conductive adhesive film between the third core die of the uppermost core die block of the plurality of core die blocks and the fourth core die.

20. The semiconductor package of claim 16, further comprising:
a fourth core die and a fifth core die arranged side by side on the second surface of the first core die and between the buffer die and a lowermost core die block of the plurality of core die blocks; and
a third non-conductive adhesive film positioned between the buffer die and the fourth core die, and a fourth non-conductive adhesive film positioned spaced apart from the third non-conductive adhesive film between the buffer die and the fifth core die.
